(19) United States
(12) Patent Application Publication
(10) Pub. No.: US 2022/0149856 A1
(43) Pub. Date: May 12, 2022

(54) BRIDGE SENSOR DC ERROR CANCELLATION SCHEME

(71) Applicant: MICROSOFT TECHNOLOGY LICENSING, LLC, Redmond, WA (US)

(72) Inventors: Chang Joon PARK, Sunnyvale, CA (US); Martin Francis GALINSKI, Santa Clara, CA (US); Zhuo Yi CAO, Mountain View, CA (US)

(21) Appl. No.: 17/095,701

(22) Filed: Nov. 11, 2020

(51) Int. Cl. H03M 1/08; G01R 17/10; H03K 17/687; G01L 1/16

(52) U.S. Cl. CPC H03M 1/0863; G01L 1/16; H03K 17/687; G01R 17/105

(57) ABSTRACT

The disclosed techniques provide a number of technical benefits by providing a bridge sensor DC error cancellation scheme. In one embodiment, a system includes a piezoresistive Wheatstone bridge, a number of switches, and a non-overlapping clock. The system can mitigate noise and other errors by subtraction of the two differential outputs of the system between a first phase and a second phase of a clock input controlling the switches. In some embodiments, the system can also include differential programmable gain amplifiers and a multi-bit analog-to-digital converter. By providing a bridge sensor DC error cancellation scheme for producing an analog output, a system can be used to generate a stable digital output of at the analog-to-digital converter.

### BACKGROUND

The micro-electromechanical system (MEMs) mirror technology for laser displays is sensitive to mirror positions. Therefore, the MEMs mirror position sensing is critical for the display quality and reliability of the mirrors. One of the ways to detect the mirror position is sensing the silicon resistivity changes of the PZR fabricated on the same wafer with the MEMs mirrors. There could be several error sources like 1/f noise, offset under PVT variations, thermocouples with poor sensing accuracy, etc. To address such issues, existing systems can use one of a number of stabilization schemes. For example, the chopper stabilization scheme is popular technique for sensing application to achieve high accuracy system without the errors.

Although some existing systems can utilize stabilization schemes, existing techniques have a number of drawbacks. For example, existing systems may not be configured to utilize multiple factors to enable a stabilization scheme to be used in different applications and different use scenarios. In addition, when it comes to stabilization schemes, e.g., error cancellation schemes, there is a continual need to further develop the accuracy and reliability of existing systems.

### SUMMARY

The disclosed techniques provide a number of technical benefits by providing a bridge sensor DC error cancellation scheme. In one embodiment, a system includes a piezoresistive Wheatstone bridge, a number of switches, and a non-overlapping clock. The system can differentially mitigate noise and other error sources applied to a system and provide a differential output that cancels common mode noise and errors. In some embodiments, the system can also include differential programmable gain amplifiers and a multi-bit analog-to-digital converter (ADC). By providing a bridge sensor DC error cancellation scheme for producing an analog output, a system can be used to generate a stable digital output of at the analog-to-digital converter.

Some bridge circuits are used for sensor applications. However, the signal from the bridge sensor itself is very small and has several error sources with DC-excitation. Also, it can be difficult to distinguish between the signal from the bridge and the error sources like 1/f noise, offsets and parasitic thermocouples. The techniques disclosed herein separates the actual signal from the error sources at the output to get the target Signal-to-Noise Ratio (SNR). One principle of the disclosed techniques is applying a chopper stabilization scheme that eliminates the error sources at the output. The switches, which can be in the form of MOS/Bipolar switches, are connected between the positive, negative biases and the piezoresistive bridge is controlled by the non-overlapping clock. The induced DC errors can be removed by the reversed polarity of the bias for the piezoresistive bridge between measurements. As a result, the only doubled differential output signal can be obtained at the output.

In one example, the piezoresistive effect can be used to detect MEMS mirror position since mechanical stress created by the oscillating structure makes silicon resistivity changes. There are several error sources like 1/f Noise, offset under PVT variations and parasitic thermocouples. In order to achieve a reasonable SNR for accurate control, the actual signal needs to be differentiated from the error sources and they need to be eliminated from the output since the sensed signal is very small. Such needs are met with the system disclosed herein.

Features and technical benefits other than those explicitly described above will be apparent from a reading of the following Detailed Description and a review of the associated drawings. This Summary is provided to introduce a selection of concepts in a simplified form that are further described below in the Detailed Description. This Summary is not intended to identify key or essential features of the claimed subject matter, nor is it intended to be used as an aid in determining the scope of the claimed subject matter. The term “techniques,” for instance, may refer to system(s), method(s), computer-readable instructions, module(s), algorithms, hardware logic, and/or operation(s) as permitted by the context described above and throughout the document.

### BRIEF DESCRIPTION OF THE DRAWINGS

The Detailed Description is described with reference to the accompanying figures. In the figures, the left-most digit(s) of a reference number identifies the figure in which the reference number first appears. The same reference numbers in different figures indicate similar or identical items. References made to individual items of a plurality of items can use a reference number with a letter of a sequence of letters to refer to each individual item. Generic references to the items may use the specific reference number without the sequence of letters.

FIG. 1 is a block diagram of a system comprising a piezoresistive bridge circuit configured to differentially mitigate noise and other error sources.

FIG. 2 is a block diagram of a system comprising transistors operating switches for controlling a piezoresistive bridge circuit configured to differentially mitigate noise and other error sources.

FIG. 3 is a block diagram of a system comprising a piezoresistive bridge circuit configured to differentially mitigate noise and other error sources with a gain stage and an analog-to-digital converter.

### DETAILED DESCRIPTION

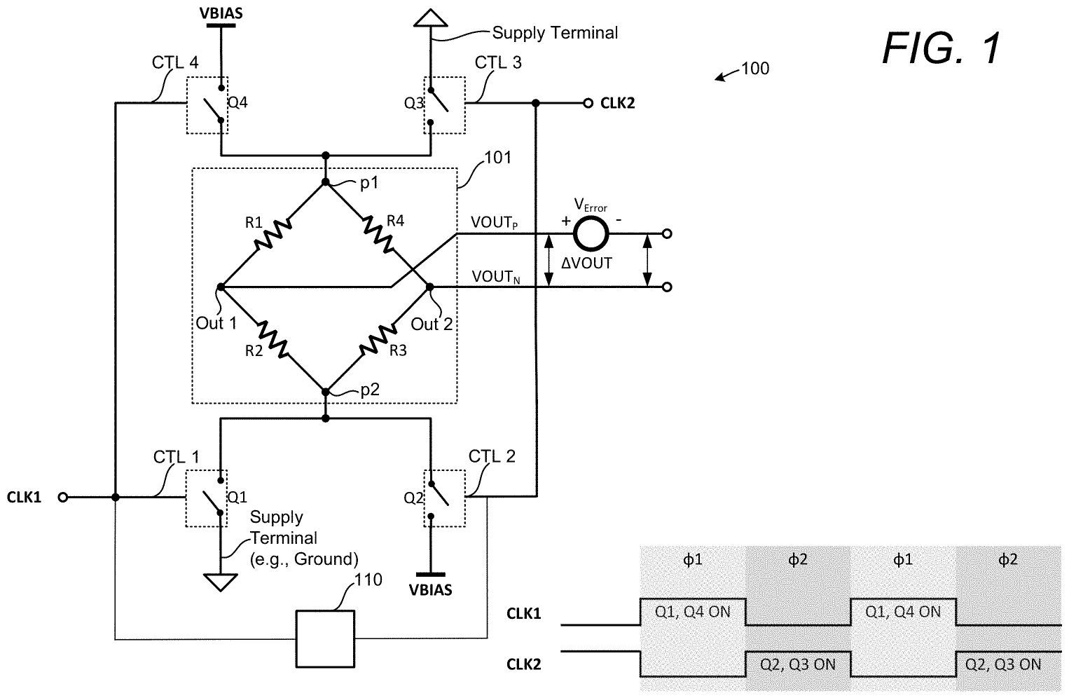

FIG. 1 illustrates a system 100 configured to differentially mitigate noise and other error sources applied to the system 100. The system 100 comprises a piezoresistive bridge circuit 101, a number of switch circuits (Q1-Q4), and a switch control circuit. The piezoresistive bridge circuit 101 includes a first power terminal p1, a second power terminal p2, a first output terminal (Out 1) and a second output terminal (Out 2). The first switch circuit Q1 is configured to selectively couple a supply terminal, e.g., ground, to the second power terminal p2 responsive to an activation of a first control signal CTL 1. The second switch circuit Q2 is configured to selectively couple a bias voltage (Vbias) to the second power terminal p2 responsive to an activation of a second control signal CTL 2. The third switch circuit Q3 is configured to selectively couple the supply terminal to the first power terminal p1 responsive to an activation of a third control signal CTL 3. The fourth switch circuit Q4 is configured to selectively couple the bias voltage (Vbias) to the first power terminal power 1 responsive to an activation of a fourth control signal CTL 4.

The switch control circuit 110 is adapted to selectively control the first control signal CTL 1, the second control signal CTL 2, the third control signal CTL 3, and the fourth control signal CTL 4 responsive to an input clock. During a first phase of the input clock, the first control signal CTL 1 and the fourth control signal CTL 4 are concurrently activated. In response, the first switch circuit Q1 couples the supply terminal (ground) to the second power terminal p2 responsive to the activation of a first control signal CTL 1. In addition, during the first phase of the input clock, the fourth switch circuit Q4 couples the bias voltage (Vbias) to the first power terminal p1.

During the first phase of the input clock, the second switch circuit Q2 maintains an open circuit between the bias voltage (Vbias) and the second power terminal p2 responsive to the second control signal CTL 2 not being activated. During the first phase of the input clock, the third switch circuit Q3 maintains an open circuit between the supply terminal and the first power terminal p1 responsive to the third control signal CTL 3 not being activated.

During a second phase of the input clock, the second control signal CTL 2 and the third control signal CTL 3 are concurrently activated. In response, during the second phase of the input clock, the second switch circuit Q2 couples the bias voltage (Vbias) to the second power terminal p2 responsive to the activation of the second control signal CTL 2. During the second phase of the input clock, the third switch circuit Q3 couples the supply terminal to the first power terminal p1 responsive to the activation of a third control signal CTL 3.

During a second phase of the input clock, the first switch circuit Q1 maintains an open circuit between the supply terminal and the second power terminal p2 responsive to the first control signal CTL 1 not being activated. During a second phase of the input clock, the fourth switch circuit Q4 maintains an open circuit between the bias voltage (Vbias) and the first power terminal p1 responsive to the fourth control signal CTL 4 not being activated. The errors are cancelled by subtracting the differential outputs between the first phase and the second phase. The two cycles can alternate over time, as shown.

In one illustrative example, the piezoresistive bridge circuit 101 comprises four resistors. A first resistor (R1) is coupled between the first power terminal p1 and the first output terminal (Out 1). A second resistor (R2) is coupled between the second power terminal p2 and the first output terminal (Out 1). A third resistor (R3) is coupled between the second power terminal p2 and the second output terminal (Out 2). A fourth resistor (R4) coupled between the first power terminal p1 and the second output terminal (Out 2). The values of the resistors can be all within a threshold resistance value of one another. The resistance values can be any suitable value, e.g., thousands of ohms to milli-ohms, etc.

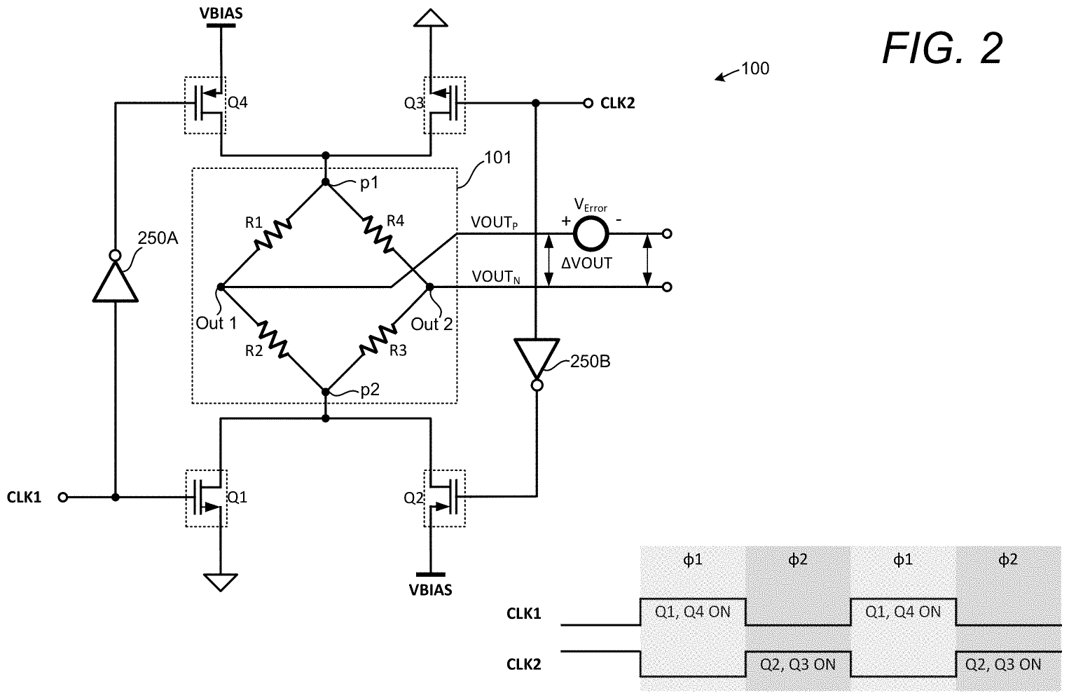

As shown in FIG. 2, the switches (Q1-Q4) can be in the form of transistors suitable for providing near closed or closed circuits between two nodes in response to an activated input, and open circuits or near open circuits when the input is not activated. In this example, the first switch Q1 is an N-channel MOSFET transistor with the drain coupled to the second power terminal p2, the gate coupled to a first clock input, and a source coupled to the supply terminal (ground). The fourth switch Q4 is a P-channel MOSFET transistor with the drain coupled to the first power terminal p1, the gate coupled to an inverted first clock input via the output of a first inverter 250A that has an input coupled to the first clock input. The source of the fourth switch Q4 is coupled to the bias voltage (Vbias).

The third switch Q3 is an N-channel MOSFET transistor with the drain coupled to the first power terminal p1, the gate coupled to a second clock input, and a source coupled to the supply terminal (ground). The second switch Q2 is a P-channel MOSFET transistor with the drain coupled to the second power terminal p2, the gate coupled to an inverted second clock input via an output of a second inverter 250B that has an input coupled to the second clock input. The source of the second switch Q2 is coupled to the bias voltage (Vbias). This embodiment enables the system 100 to operate with two clock inputs using inverters that are arranged according to the implementation using particular transistors.

In the disclosed systems, as shown in EQUATION 1 below, the errors, e.g., noise, can be cancelled by subtraction of the two differential outputs between the first phase and the second phase. The output can be represented as a VOUT_{Diff1} for the first phase, and a VOUT_{Diff2} for the second phase in the following equation, which shows that the error in the voltage is cancelled by the differential configuration.

ϕ1: VOUT_{DIFF1}=(VOUT_{P}−V_{Error})−VOUT_{N}

ϕ2: VOUT_{DIFF2}=VOUT_{N}−(VOUT_{P}−V_{Error})

VOUT_{DIFF}=VOUT_{DIFF1}−VOUT_{DIFF2}
Φ1: 1^{ST} Measurement
Φ2: 2^{nd} Measurement

ΔVOUT=VOUT_{P}−VOUT_{N}
V_{Errorv}: All the induced DC and low frequency Errors

VOUT_{DIFF}=2ΔVOUT EQUATION 1

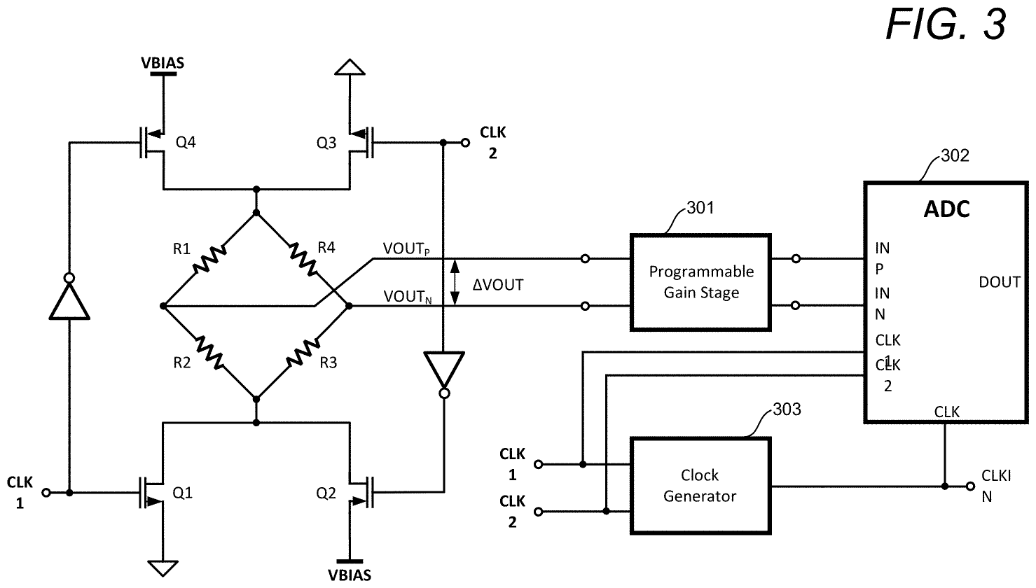

The disclosed techniques can apply to a wide range of applications. In one example, the piezoresistive effect can be used to detect MEMs mirror position. There are several error sources like 1/f Noise, offset under PVT variations and parasitic thermocouples. In order to achieve a reasonable SNR for accurate control, the actual signal needs to be differentiated from the error sources and they need to be eliminated from the output since the sensed signal is very small. Such needs are met with the system disclosed herein. FIG. 3 shows an example of other components that can be used in such embodiments.

FIG. 3 shows aspects of the embodiment of FIG. 2 with the addition of a programmable gain stage 301 and, an analog-to-digital converter (ADC) 302, and a clock generator 303. The programmable gain stage 301 comprises a gain stage input coupled to the differential output across the first output terminals and second output terminals. The programmable gain stage 301 comprises gain stage output terminals. The programmable gain stage is configured to receive a signal at the gain stage input and amplify the received signal for generation of an output signal at the gain stage output terminals.

The ADC 302 includes analog input terminals that are each coupled to the gain stage output terminals. The ADC 302 coordinates with clock input signals from the clock generator 303, where the clock input signals are also provided to the switches coupled to the piezoresistive bridge circuit 101. The ADC 302 generates a digital output (Dₒᵤₜ) that is based on the voltage provided at the analog input terminals. In some configurations, the gain stage 301, ADC 302, and the clock generator 303 can be integrated as one chipset solution for providing improved synchronization and accuracy during operation.

Throughout the specification and claims, the following terms take the meanings explicitly associated herein, unless the context clearly dictates otherwise. The meaning of “a,” “an,” and “the” includes plural reference, the meaning of “in” includes “in” and “on.” The term “connected” means a direct electrical connection between the items connected, without any intermediate devices. The term “coupled” means a direct electrical connection between the items connected, or an indirect connection through one or more passive or active intermediary devices and/or components. The terms “circuit” and “component” means either a single component or a multiplicity of components, either active and/or passive, that are coupled to provide a desired function. The term “signal” means at least a wattage, current, voltage, or data signal. The terms, “gate,” “drain,” and “source,” can also mean a “base,” “collector” and “emitter,” and/or equivalent parts.

The disclosure presented herein may be considered in view of the following example clauses:

Example Clause 1: A system configured to differentially mitigate noise and other errors applied to the system the system comprising: a piezoresistive bridge circuit having a first power terminal, a second power terminal, a first output terminal and a second output terminal; a first switch circuit configured to selectively couple a supply terminal to the second power terminal responsive to an activation of a first control signal; a second switch circuit configured to selectively couple a bias voltage to the second power terminal responsive to an activation of a second control signal; a third switch circuit configured to selectively couple the supply terminal to the first power terminal responsive to an activation of a third control signal; a fourth switch circuit configured to selectively couple the bias voltage to the first power terminal responsive to an activation of a fourth control signal; a switch control circuit adapted to selectively control the first control signal, the second control signal, the third control signal, and the fourth control signal responsive to an input clock, such that: during a first phase of the input clock, the first control signal and the fourth control signal are concurrently activated, during a second phase of the input clock, the second control signal and the third control signal are concurrently activated, wherein the noise and errors are cancelled by subtraction of two differential outputs across the first output terminal and second output terminal between, e.g., over the period of, the first phase and the second phase.

Example Clause 2: The system of clause 1, wherein the piezoresistive bridge circuit comprises a first resistor coupled between the first power terminal and the first output terminal, a second resistor coupled between the second power terminal and the first output terminal, a third resistor coupled between the second power terminal and the second output terminal, and a fourth resistor coupled between the first power terminal and the second output terminal.

Example Clause 3: The system of clauses 1 and 2, wherein the first resistor, the second resistor, the third resistor, and the fourth resistor are within a threshold resistance value of one another.

Example Clause 4: The system of clauses 1 through 3, wherein during the first phase of the input clock, the second switch circuit maintains an open circuit between the bias voltage and the second power terminal responsive to the second control signal not being activated, wherein the third switch circuit maintains an open circuit between the supply terminal and the first power terminal responsive to the third control signal not being activated.

Example Clause 5: The system of clauses 1 through 4, wherein during the second phase of the input clock, the first switch circuit maintains an open circuit between the supply terminal and the second power terminal responsive to the first control signal not being activated, and wherein the fourth switch circuit maintains an open circuit between the bias voltage and the first power terminal responsive to the fourth control signal not being activated.

Example Clause 6: The system of clauses 1 through 5, wherein the first switch is an N-channel MOSFET transistor with a drain coupled to the second power terminal, a gate coupled to a first clock input, and a source coupled to the supply terminal, wherein the fourth switch is a P-channel MOSFET transistor with a drain coupled to the first power terminal, a gate coupled to an inverted signal of the first clock input generated by an output of a first inverter that has an input coupled to the first clock input, wherein a source of the fourth switch is coupled to the bias voltage.

Example Clause 7: The system of clauses 1 through 6, wherein the third switch is an N-channel MOSFET transistor with drain coupled to the first power terminal, a gate coupled to a second clock input, and a source coupled to the supply terminal, wherein the second switch is a P-channel MOSFET transistor with a drain coupled to the second power terminal, a gate coupled to an inverted second clock input that is generated by an output of a second inverter that has an input coupled to the second clock input, wherein source of the second switch is coupled to the bias voltage.

Example Clause 8: The system of clauses 1 through 7, wherein the system further comprises a programmable gain stage, an analog-to-digital converter, and a clock generator, wherein the programmable gain stage comprises a gain stage input coupled to the differential output across the first output terminal and second output terminal, the programmable gain stage is configured to receive the differential output at the gain stage input and amplify the received signal for generation of an amplified output signal at a gain stage output terminal, the analog-to-digital converter comprising analog input terminals that are each coupled to the gain stage output terminals, the analog-to-digital converter configured to coordinate with clock input signals from the clock generator, wherein the clock input signals are also provided to the switches coupled to the piezoresistive bridge circuit, the analog-to-digital converter configured to generate a digital output that is based on the voltage provided at the analog input terminals.

Example Clause 9: A system configured to differentially mitigate noise and other errors applied to the system, the system comprising: a piezoresistive bridge circuit having a first power terminal, a second power terminal, a first output terminal and a second output terminal, and a plurality of resistors having an arrangement that receives an input signal at the first power terminal and the second power terminal to produce differential outputs at the first output terminal and the second output terminal; a first switch circuit configured to selectively couple a supply terminal to the second power terminal responsive to an activation of a first control signal; a second switch circuit configured to selectively couple a bias voltage to the second power terminal responsive to an activation of a second control signal; a third switch circuit configured to selectively couple the supply terminal to the first power terminal responsive to an activation of a third control signal; a fourth switch circuit configured to selectively couple the bias voltage to the first power terminal responsive to an activation of a fourth control signal; a switch control circuit adapted to selectively control the first control signal, the second control signal, the third control signal, and the fourth control signal responsive to an input clock, such that: during a first phase of the input clock, the first control signal and the fourth control signal are concurrently activated, during a second phase of the input clock, the second control signal and the third control signal are concurrently activated, wherein the noise and the other errors are cancelled by subtraction of the differential outputs between the first phase and the second phase.

Example Clause 10: The system of clause 9, wherein the plurality of resistors comprises a first resistor coupled between the first power terminal and the first output terminal, a second resistor coupled between the second power terminal and the first output terminal, a third resistor coupled between the second power terminal and the second output terminal, and a fourth resistor coupled between the first power terminal and the second output terminal, wherein the first resistor, the second resistor, the third resistor, and the fourth resistor are within a threshold resistance value of one another.

Example Clause 11: The system of clauses 9 and 10, wherein during the first phase of the input clock, the second switch circuit maintains an open circuit between the bias voltage and the second power terminal responsive to the second control signal not being activated, wherein the third switch circuit maintains an open circuit between the supply terminal and the first power terminal responsive to the third control signal not being activated.

Example Clause 12: The system of clauses 9 through 11, wherein during the second phase of the input clock, the first switch circuit maintains an open circuit between the supply terminal and the second power terminal responsive to the first control signal not being activated, and wherein the fourth switch circuit maintains an open circuit between the bias voltage and the first power terminal responsive to the fourth control signal not being activated.

Example Clause 13: The system of clauses 9 through 12, wherein the first switch is an N-channel MOSFET transistor with a drain coupled to the second power terminal, a gate coupled to a first clock input, and a source coupled to the supply terminal, wherein the fourth switch is a P-channel MOSFET transistor with a drain coupled to the first power terminal, a gate coupled to an inverted signal of the first clock input generated by an output of a first inverter that has an input coupled to the first clock input, wherein a source of the fourth switch Q4 is coupled to the bias voltage.

Example Clause 14: The system of clauses 9 through 13, wherein the third switch is an N-channel MOSFET transistor with drain coupled to the first power terminal, a gate coupled to a second clock input, and a source coupled to the supply terminal, wherein the second switch is a P-channel MOSFET transistor with a drain coupled to the second power terminal, a gate coupled to an inverted second clock input that is generated by an output of a second inverter that has an input coupled to the second clock input, wherein source of the second switch is coupled to the bias voltage.

Example Clause 15: A system configured to differentially mitigate noise and other errors applied to the system, the system comprising: a piezoresistive bridge circuit having a first power terminal, a second power terminal, a first output terminal and a second output terminal, and a plurality of resistors having an arrangement that receives an input signal at the first power terminal and the second power terminal to produce differential outputs at the first output terminal and the second output terminal; a first switch circuit configured to selectively couple a supply terminal to the second power terminal responsive to an activation of a first control signal; a second switch circuit configured to selectively couple a bias voltage to the second power terminal responsive to an activation of a second control signal; a third switch circuit configured to selectively couple the supply terminal to the first power terminal responsive to an activation of a third control signal; a fourth switch circuit configured to selectively couple the bias voltage to the first power terminal responsive to an activation of a fourth control signal; a switch control circuit adapted to selectively control the first control signal, the second control signal, the third control signal, and the fourth control signal responsive to an input clock, such that: during a first phase of the input clock, the first control signal and the fourth control signal are concurrently activated, during a second phase of the input clock, the second control signal and the third control signal are concurrently activated, wherein the plurality of resistors configured to generate the differential output across the first output terminal and second output terminal based on the input signal during the first phase of the input clock and the second phase of the input clock, wherein the noise and the other errors are cancelled by subtraction of the differential outputs between the first phase and the second phase; and an analog-to-digital converter configured to receive the differential outputs through a gain stage amplifier, wherein the analog-to-digital converter generates a digital output based on a voltage of the differential outputs.

Example Clause 16: The system of clause 15, wherein the plurality of resistors comprises a first resistor coupled between the first power terminal and the first output terminal, a second resistor coupled between the second power terminal and the first output terminal, a third resistor coupled between the second power terminal and the second output terminal, and a fourth resistor coupled between the first power terminal and the second output terminal, wherein the first resistor, the second resistor, the third resistor, and the fourth resistor are within a threshold resistance value of one another.

Example Clause 17: The system of clauses 15 and 16, wherein during the first phase of the input clock, the second switch circuit maintains an open circuit between the bias voltage and the second power terminal responsive to the second control signal not being activated, wherein the third switch circuit maintains an open circuit between the supply terminal and the first power terminal responsive to the third control signal not being activated.

Example Clause 18: The system of clauses 15 through 17, wherein during the second phase of the input clock, the first switch circuit maintains an open circuit between the supply terminal and the second power terminal responsive to the first control signal not being activated, and wherein the fourth switch circuit maintains an open circuit between the bias voltage and the first power terminal responsive to the fourth control signal not being activated.

Example Clause 19: The system of clauses 15 through 18, wherein the first switch is an N-channel MOSFET transistor with a drain coupled to the second power terminal, a gate coupled to a first clock input, and a source coupled to the supply terminal, wherein the fourth switch is a P-channel MOSFET transistor with a drain coupled to the first power terminal, a gate coupled to an inverted signal of the first clock input generated by an output of a first inverter that has an input coupled to the first clock input, wherein a source of the fourth switch Q4 is coupled to the bias voltage.

Example Clause 20: The system of clauses 15 through 19, wherein the third switch is an N-channel MOSFET transistor with drain coupled to the first power terminal, a gate coupled to a second clock input, and a source coupled to the supply terminal, wherein the second switch is a P-channel MOSFET transistor with a drain coupled to the second power terminal, a gate coupled to an inverted second clock input that is generated by an output of a second inverter that has an input coupled to the second clock input, wherein source of the second switch is coupled to the bias voltage.

In closing, although the various configurations have been described in language specific to structural features and/or methodological acts, it is to be understood that the subject matter defined in the appended representations is not necessarily limited to the specific features or acts described. Rather, the specific features and acts are disclosed as example forms of implementing the claimed subject matter.

1. A system configured to differentially mitigate noise and other errors applied to the system the system comprising:
a piezoresistive bridge circuit having a first power terminal, a second power terminal, a first output terminal and a second output terminal;
a first switch circuit configured to selectively couple a supply terminal to the second power terminal responsive to an activation of a first control signal;
a second switch circuit configured to selectively couple a bias voltage to the second power terminal responsive to an activation of a second control signal;
a third switch circuit configured to selectively couple the supply terminal to the first power terminal responsive to an activation of a third control signal;
a fourth switch circuit configured to selectively couple the bias voltage to the first power terminal responsive to an activation of a fourth control signal;
a switch control circuit adapted to selectively control the first control signal, the second control signal, the third control signal, and the fourth control signal responsive to an input clock, such that:
during a first phase of the input clock, the first control signal and the fourth control signal are concurrently activated,
during a second phase of the input clock, the second control signal and the third control signal are concurrently activated,
wherein the noise and errors are cancelled by subtraction of two differential outputs across the first output terminal and second output terminal between the first phase and the second phase.

2. The system of claim 1, wherein the piezoresistive bridge circuit comprises a first resistor coupled between the first power terminal and the first output terminal, a second resistor coupled between the second power terminal and the first output terminal, a third resistor coupled between the second power terminal and the second output terminal, and a fourth resistor coupled between the first power terminal and the second output terminal.

3. The system of claim 2, wherein the first resistor, the second resistor, the third resistor, and the fourth resistor are within a threshold resistance value of one another.

4. The system of claim 1, wherein during the first phase of the input clock, the second switch circuit maintains an open circuit between the bias voltage and the second power terminal responsive to the second control signal not being activated, wherein the third switch circuit maintains an open circuit between the supply terminal and the first power terminal responsive to the third control signal not being activated.

5. The system of claim 1, wherein during the second phase of the input clock, the first switch circuit maintains an open circuit between the supply terminal and the second power terminal responsive to the first control signal not being activated, and wherein the fourth switch circuit maintains an open circuit between the bias voltage and the first power terminal responsive to the fourth control signal not being activated.

6. The system of claim 1, wherein the first switch is an N-channel MOSFET transistor with a drain coupled to the second power terminal, a gate coupled to a first clock input, and a source coupled to the supply terminal, wherein the fourth switch is a P-channel MOSFET transistor with a drain coupled to the first power terminal, a gate coupled to an inverted signal of the first clock input generated by an output of a first inverter that has an input coupled to the first clock input, wherein a source of the fourth switch is coupled to the bias voltage.

7. The system of claim 1, wherein the third switch is an N-channel MOSFET transistor with drain coupled to the first power terminal, a gate coupled to a second clock input, and a source coupled to the supply terminal, wherein the second switch is a P-channel MOSFET transistor with a drain coupled to the second power terminal, a gate coupled to an inverted second clock input that is generated by an output of a second inverter that has an input coupled to the second clock input, wherein source of the second switch is coupled to the bias voltage.

8. The system of claim 1, wherein the system further comprises a programmable gain stage, an analog-to-digital converter, and a clock generator, wherein the programmable gain stage comprises a gain stage input coupled to the differential output across the first output terminal and second output terminal, the programmable gain stage is configured to receive the differential output at the gain stage input and amplify the received signal for generation of an amplified output signal at a gain stage output terminal, the analog-to-digital converter comprising analog input terminals that are each coupled to the gain stage output terminals, the analog-to-digital converter configured to coordinate with clock input signals from the clock generator, wherein the clock input signals are also provided to the switches coupled to the piezoresistive bridge circuit, the analog-to-digital converter configured to generate a digital output that is based on the voltage provided at the analog input terminals.

9. A system configured to differentially mitigate noise and other errors applied to the system, the system comprising:
a piezoresistive bridge circuit having a first power terminal, a second power terminal, a first output terminal and a second output terminal, and a plurality of resistors having an arrangement that receives an input signal at the first power terminal and the second power terminal to produce differential outputs at the first output terminal and the second output terminal;
a first switch circuit configured to selectively couple a supply terminal to the second power terminal responsive to an activation of a first control signal;
a second switch circuit configured to selectively couple a bias voltage to the second power terminal responsive to an activation of a second control signal;
a third switch circuit configured to selectively couple the supply terminal to the first power terminal responsive to an activation of a third control signal;
a fourth switch circuit configured to selectively couple the bias voltage to the first power terminal responsive to an activation of a fourth control signal;
a switch control circuit adapted to selectively control the first control signal, the second control signal, the third control signal, and the fourth control signal responsive to an input clock, such that:
during a first phase of the input clock, the first control signal and the fourth control signal are concurrently activated,
during a second phase of the input clock, the second control signal and the third control signal are concurrently activated,
wherein the noise and the other errors are cancelled by subtraction of the differential outputs between the first phase and the second phase.

10. The system of claim 9, wherein the plurality of resistors comprises a first resistor coupled between the first power terminal and the first output terminal, a second resistor coupled between the second power terminal and the first output terminal, a third resistor coupled between the second power terminal and the second output terminal, and a fourth resistor coupled between the first power terminal and the second output terminal, wherein the first resistor, the second resistor, the third resistor, and the fourth resistor are within a threshold resistance value of one another.

11. The system of claim 9, wherein during the first phase of the input clock, the second switch circuit maintains an open circuit between the bias voltage and the second power terminal responsive to the second control signal not being activated, wherein the third switch circuit maintains an open circuit between the supply terminal and the first power terminal responsive to the third control signal not being activated.

12. The system of claim 9, wherein during the second phase of the input clock, the first switch circuit maintains an open circuit between the supply terminal and the second power terminal responsive to the first control signal not being activated, and wherein the fourth switch circuit maintains an open circuit between the bias voltage and the first power terminal responsive to the fourth control signal not being activated.

13. The system of claim 9, wherein the first switch is an N-channel MOSFET transistor with a drain coupled to the second power terminal, a gate coupled to a first clock input, and a source coupled to the supply terminal, wherein the fourth switch is a P-channel MOSFET transistor with a drain coupled to the first power terminal, a gate coupled to an inverted signal of the first clock input generated by an output of a first inverter that has an input coupled to the first clock input, wherein a source of the fourth switch Q4 is coupled to the bias voltage.

14. The system of claim 9, wherein the third switch is an N-channel MOSFET transistor with drain coupled to the first power terminal, a gate coupled to a second clock input, and a source coupled to the supply terminal, wherein the second switch is a P-channel MOSFET transistor with a drain coupled to the second power terminal, a gate coupled to an inverted second clock input that is generated by an output of a second inverter that has an input coupled to the second clock input, wherein source of the second switch is coupled to the bias voltage.

15. A system configured to differentially mitigate noise and other errors applied to the system, the system comprising:
a piezoresistive bridge circuit having a first power terminal, a second power terminal, a first output terminal and a second output terminal, and a plurality of resistors having an arrangement that receives an input signal at the first power terminal and the second power terminal to produce differential outputs at the first output terminal and the second output terminal;
a first switch circuit configured to selectively couple a supply terminal to the second power terminal responsive to an activation of a first control signal;
a second switch circuit configured to selectively couple a bias voltage to the second power terminal responsive to an activation of a second control signal;
a third switch circuit configured to selectively couple the supply terminal to the first power terminal responsive to an activation of a third control signal;
a fourth switch circuit configured to selectively couple the bias voltage to the first power terminal responsive to an activation of a fourth control signal;
a switch control circuit adapted to selectively control the first control signal, the second control signal, the third control signal, and the fourth control signal responsive to an input clock, such that: during a first phase of the input clock, the first control signal and the fourth control signal are concurrently activated, during a second phase of the input clock, the second control signal and the third control signal are concurrently activated, wherein the plurality of resistors configured to generate the differential output across the first output terminal and second output terminal based on the input signal during the first phase of the input clock and the second phase of the input clock, wherein the noise and the other errors are cancelled by subtraction of the differential outputs between the first phase and the second phase; and
an analog-to-digital converter configured to receive the differential outputs through a gain stage amplifier, wherein the analog-to-digital converter generates a digital output based on a voltage of the differential outputs.

16. The system of claim 15, wherein the plurality of resistors comprises a first resistor coupled between the first power terminal and the first output terminal, a second resistor coupled between the second power terminal and the first output terminal, a third resistor coupled between the second power terminal and the second output terminal, and a fourth resistor coupled between the first power terminal and the second output terminal, wherein the first resistor, the second resistor, the third resistor, and the fourth resistor are within a threshold resistance value of one another.

17. The system of claim 15, wherein during the first phase of the input clock, the second switch circuit maintains an open circuit between the bias voltage and the second power terminal responsive to the second control signal not being activated, wherein the third switch circuit maintains an open circuit between the supply terminal and the first power terminal responsive to the third control signal not being activated.

18. The system of claim 15, wherein during the second phase of the input clock, the first switch circuit maintains an open circuit between the supply terminal and the second power terminal responsive to the first control signal not being activated, and wherein the fourth switch circuit maintains an open circuit between the bias voltage and the first power terminal responsive to the fourth control signal not being activated.

19. The system of claim 15, wherein the first switch is an N-channel MOSFET transistor with a drain coupled to the second power terminal, a gate coupled to a first clock input, and a source coupled to the supply terminal, wherein the fourth switch is a P-channel MOSFET transistor with a drain coupled to the first power terminal, a gate coupled to an inverted signal of the first clock input generated by an output of a first inverter that has an input coupled to the first clock input, wherein a source of the fourth switch Q4 is coupled to the bias voltage.

20. The system of claim 15, wherein the third switch is an N-channel MOSFET transistor with drain coupled to the first power terminal, a gate coupled to a second clock input, and a source coupled to the supply terminal, wherein the second switch is a P-channel MOSFET transistor with a drain coupled to the second power terminal, a gate coupled to an inverted second clock input that is generated by an output of a second inverter that has an input coupled to the second clock input, wherein source of the second switch is coupled to the bias voltage.
